(19) United States
(12) Patent Application Publication
(10) Pub. No.: US 2025/0124975 A1
(43) Pub. Date: Apr. 17, 2025

(54) UNIT CELL CIRCUIT AND MEMORY DEVICE INCLUDING THE SAME

(71) Applicant: SAMSUNG ELECTRONICS CO., LTD., SUWON-SI (KR)

(72) Inventors: JUNG-MYUNG KANG, SUWON-SI (KR); SEONG-OOK JUNG, SEOUL (KR); KEONHEE CHO, SEOUL (KR); GISEOK KIM, SEOUL (KR); SEKEON KIM, SEOUL (KR)

(73) Assignee: UIF (University-Industry Foundation), Yonsei University, SEOUL (KR)

(21) Appl. No.: 18/914,082

(22) Filed: Oct. 12, 2024

(30) Foreign Application Priority Data
Oct. 13, 2023 (KR) 10-2023-0137128
Mar. 14, 2024 (KR) 10-2024-0036077

(51) Int. Cl. G11C 11/412; G11C 11/418; G11C 11/419

(52) U.S. Cl. CPC G11C 11/412; G11C 11/418; G11C 11/419

(57) ABSTRACT

Disclosed is a unit cell circuit of a memory cell array, the unit cell circuit having a sub-cell array including a plurality of memory cells each connected to a supply line, and an assist circuit connected to the sub-cell array through the supply line that pre-charges the supply line with a supply voltage during a stand-by mode based on a control signal and blocks the supply line upon initiation of a write operation.

### CROSS-REFERENCE

This application claims priority under 35 U.S.C. § 119 to Korean Patent Application Numbers 10-2023-0137128 filed on Oct. 13, 2023 and 10-2024-0036077 filed on Mar. 14, 2024, each in the Korean Intellectual Property Office (KIPO), the disclosures of which are incorporated by reference herein in their entireties.

### FIELD

The present disclosure generally relates to memory devices, and more particularly relates to a unit cell circuit and a memory device including the same.

### DISCUSSION

A System-On-Chip (SoC) may be used in a variety of applications, such as mobile devices like mobile phones, tablets, and smart watches, as well as automobiles, smart home systems, and medical devices. As technology develops, SoCs are desired to be high-performance and efficient in terms of energy and area. Operating voltage scaling is a technology for reducing both active power and static power and implementing an energy-efficient SoC by lowering the operating voltage of the SoC.

However, a Static Random Access Memory (SRAM), used as a cache memory of the SoCs, may present a bottleneck in lowering the operating voltage of the SoC due to its high minimum operating voltage. For example, an SRAM may have a high minimum operating voltage due to contention within memory cells during read/write operations. In addition, due to the gradually increasing threshold voltage fluctuations in SRAM cells, the increase in desired yield, and the difficulty of improving the minimum operating voltage due to improvements in the design of the cell itself, the introduction of an assist circuit for improving the minimum operating voltage is provided.

### SUMMARY

Embodiments of the present disclosure may address one or more of the above-mentioned areas, and provide a unit cell circuit for assisting a write operation and a memory device including the unit cell circuit.

According to an embodiment of the present disclosure, a unit cell circuit of a memory cell array includes a sub-cell array including a plurality of memory cells each connected to a supply line, and an assist circuit connected to the sub-cell array through the supply line and configured to pre-charge the supply line with a supply voltage during a stand-by mode based on a control signal and to block the supply line upon initiation of a write operation.

According to an embodiment of the present disclosure, a memory device includes a memory cell array including a plurality of unit cell circuits, and a row peripheral circuit configured to control the plurality of unit cell circuits, wherein each of the plurality of unit cell circuits includes a respective sub-cell array including a respective plurality of memory cells, and a respective assist circuit connected to the respective sub-cell array through a respective supply line, and configured to pre-charge the respective supply line with a supply voltage during a stand-by mode based on a control of the row peripheral circuit and to block the respective supply line upon initiation of a write operation.

According to an embodiment of the present disclosure, a memory row circuit includes a control logic circuit configured to provide a control signal; and a unit cell circuit that includes an assist circuit configured to receive the control signal, pre-charge a supply line with a supply voltage during a stand-by mode based on the control signal and to block the supply line upon initiation of a write operation; and a sub-cell array including a plurality of memory cells each connected to the supply line.

### BRIEF DESCRIPTION OF THE DRAWINGS

The above and other embodiments of the present disclosure will become apparent by describing in detail embodiments thereof with reference to the accompanying drawings.

FIG. 1 is a schematic diagram that illustrates a memory device according to an embodiment.

FIG. 2 is a hybrid schematic/graphical diagram that illustrates a unit cell circuit according to an embodiment.

FIG. 3 is a circuit diagram that illustrates a unit cell circuit according to an embodiment.

FIG. 4 is a graphical diagram that illustrates operational waveforms of comparative examples.

FIG. 5 is a graphical diagram that illustrates operational waveforms of FIG. 3.

FIG. 6 is a schematic diagram that illustrates a row peripheral circuit of FIG. 1 according to an embodiment.

FIG. 7 is a schematic diagram that illustrates a row peripheral circuit of FIG. 1 according to an embodiment.

FIG. 8 is a circuit diagram that illustrates a row decoder of FIG. 6 or of FIG. 7 according to a respective embodiment.

FIG. 9 is a circuit diagram that illustrates a control logic circuit of FIG. 6 according to an embodiment.

FIG. 10 is a hybrid block/circuit diagram that illustrates a control logic circuit and a unit cell circuit for performing a retention mode operation according to an embodiment.

FIG. 11 is a graphical diagram that illustrates operational waveforms of FIG. 10.

FIG. 12 is a circuit diagram that illustrates an assist circuit according to an embodiment.

FIG. 13 is a circuit diagram that illustrates an assist circuit according to an embodiment.

FIG. 14 is a circuit diagram that illustrates an assist circuit according to an embodiment.

FIG. 15 is a circuit diagram that illustrates an assist circuit according to an embodiment.

FIG. 16 is a circuit diagram that illustrates an assist circuit according to an embodiment.

FIG. 17 is a circuit diagram that illustrates an assist circuit according to an embodiment.

FIG. 18 is a structural diagram that illustrates a memory device according to an embodiment.

FIG. 19 is a structural diagram that illustrates a memory device according to an embodiment.

FIG. 20 is a structural diagram that illustrates a memory device according to an embodiment.

FIG. 21 is a layout diagram that illustrates a memory device, according to an embodiment.

### DETAILED DESCRIPTION

Hereinafter, embodiments of the present disclosure may be described by way of example with sufficient detail and clarity for one of ordinary skill in the pertinent art to readily implement the described and other embodiments thereof.

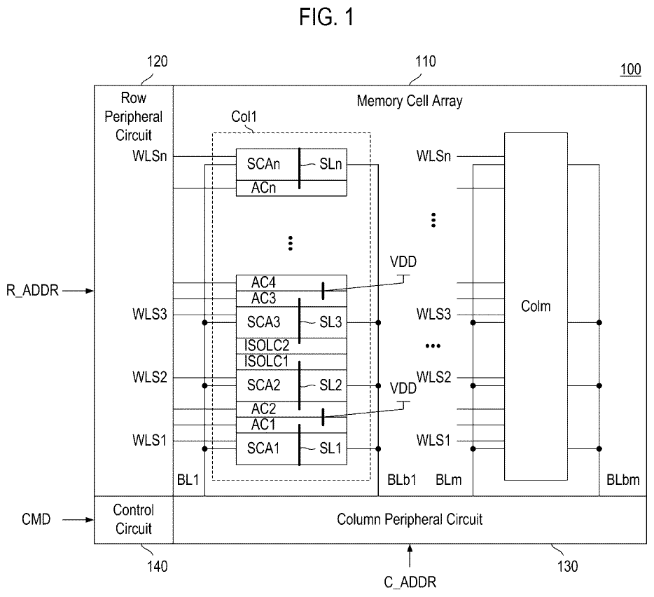

FIG. 1 illustrates a memory device, according to an embodiment.

Referring to FIG. 1, a memory device 100 according to an embodiment may include a memory cell array 110, a row peripheral circuit 120, a column peripheral circuit 130, and a control circuit 140.

The memory cell array 110 may be connected to the row peripheral circuit 120 through a plurality of word lines WLS1 to WLSn and may be connected to the column peripheral circuit 130 through a plurality of bit lines BL1 to BLm and a plurality of inverted bit lines BLb1 to BLbm. The memory cell array 110 may include a plurality of memory cells, each of which is accessed through the plurality of word lines WLS1 to WLSn, and the plurality of bit lines BL1 to BLm and the plurality of inverted bit lines BLb1 to BLbm. According to an embodiment, the plurality of memory cells included in the memory cell array 110 may be volatile memory cells, such as a static random-access memory (SRAM), a dynamic random-access memory (DRAM), etc. In addition, in an embodiment, the plurality of memory cells included in the memory cell array 110 may include non-volatile memory cells, such as flash memory, Resistive Random Access Memory (RRAM), or the like. For descriptive purposes, embodiments of the present disclosure will be described primarily with reference to the SRAM cell, without limitation thereto.

The plurality of memory cells included in the memory cell array 110 may be grouped in units of ‘k’ (where ‘k’ is a natural number), and the grouped memory cells may be defined as sub-cell arrays SCA1 to SCAn. In greater detail, each of the sub-cell arrays SCA1 to SCAn may include a plurality of ‘k’ memory cells. For example, if each memory cell has a storage capacity of ‘1’ bit, each of the sub-cell arrays SCA1 to SCAn 0 may have a storage capacity of ‘k’ bits; whereas if each memory cell has a storage capacity of ‘x’ bits, each of the sub-cell arrays SCA1 to SCAn may have a storage capacity of ‘k’ times ‘x’ bits.

As illustrated, the memory cell array 110 may be defined as including ‘m’ columns arranged as Col1 to Colm, where ‘m’ is a natural number, and each of the ‘m’ columns Col1 to Colm may be defined as including the ‘n’ sub-cell arrays SCA1 to SCAn, where ‘n’ is a natural number. Each of the columns Col1 to Colm is connected through a pair including one of bit lines BL1 to BLm paired with one of inverted bit lines BLb1 to BLbm. For example, the first column Col1 may operate by being connected to the column peripheral circuit 130 through the first bit line BL1 and the first inverted bit line (or bit line bar) BLb1 substantially complementary to the first bit line BL1. In addition, each of the sub-cell arrays SCA1 to SCAn corresponding to one row may be commonly connected to each word line.

According to an embodiment, a plurality of memory cells included in each of the sub-cell arrays SCA1 to SCAn may be connected to supply lines SL1 to SLn, respectively. The supply lines SL1 to SLn are lines to which a supply voltage VDD for an operation of each memory cell is applied, may be configured for each of the sub-cell arrays SCA1 to SCAn, and for example, ‘n’ supply lines SL1 to SLn may be configured. In greater detail, the supply line may be configured for each sub-cell array through an assist circuit. As the supply line is split for each sub-cell array, the capacitance of the supply line may be reduced.

According to an embodiment, assist circuits AC1 to ACn may be connected to the sub-cell arrays SCA1 to SCAn, respectively. In greater detail, when ‘n’ sub-cell arrays SCA1 to SCAn are configured, ‘n’ assist circuits AC1 to ACn may be configured. For convenience, one sub-cell array of the sub-cell arrays SCA1 to SCAn and one assist circuit of the assist circuits AC1 to ACn connected to the one sub-cell array may be referred to as a unit cell circuit. The memory cell array 110 includes a plurality of unit cell circuits. For example, column Col1 of the memory cell array 110 may include ‘n’ unit cell circuits.

The assist circuits AC1 to ACn may be connected to the sub-cell arrays SCA1 to SCAn, respectively, through the supply lines SL1 to SLn and may be configured to assist a write operation of each of the sub-cell arrays SCA1 to SCAn. The assist circuits AC1 to ACn may perform various operations depending on an operation of the memory device 100. First, during a stand-by mode, the assist circuits AC1 to ACn may pre-charge the supply lines SL1 to SLn to the supply voltage VDD based on a control signal from the row peripheral circuit 120. In this case, the stand-by mode may be distinguished from a retention mode, which reduces the power of peripheral circuits and reduces the leakage current of the memory cells by lowering the supply voltage of the memory cell, and may be defined as a mode in which the memory device 100 prepares to perform a read operation or a write operation. Additionally, the assist circuits AC1 to ACn may pre-charge the supply lines SL1 to SLn to the supply voltage VDD even during the read operation.

When the write operation initiates, the assist circuits AC1 to ACn may block the supply lines SL1 to SLn. Based on that the assist circuits AC1 to ACn block the supply lines SL1 to SLn, the voltage of the supply lines SL1 to SLn collapses from the supply voltage VDD that is pre-charged during the write operation. As the supply voltage VDD collapses, the ability to maintain data previously stored in each memory cell decreases. For example, when the memory cell is an SRAM cell according to an embodiment described above, the level of the supply voltage VDD directly supplied to pull-up transistors may decrease, thereby decreasing pull-up performance. As pull-up performance decreases, the write current path with respect to the bit lines BL1 to BLm and the inverted bit lines BLb1 to BLbm may be formed to be stronger, and thus the data to be finally written may be assisted in the writing to the memory cell.

According to an embodiment, the assist circuits AC1 to ACn may be configured to form a pull-up current to the supply lines SL1 to SLn as the voltage of the supply lines SL1 to SLn collapses after the write operation initiates. As the pull-up current is formed, the operating voltage of the sub-cell arrays SCA1 to SCAn may be prevented from collapsing excessively.

Based on a successful write operation on one of the plurality of memory cells, the voltage of the supply lines SL1 to SLn will stop collapsing. In greater detail, when the write operation is successful, the write current path with respect to the bit lines BL1 to BLm and the inverted bit lines BLb1 to BLbm is blocked, so the voltage of the supply lines SL1 to SLn no longer drops.

The row peripheral circuit 120 is connected to the memory cell array 110 through the plurality of word lines WLS1 to WLSn, and may activate one of the plurality of word lines WLS1 to WLSn based on a row address R_ADDR. Accordingly, the memory cells connected to the activated word line may be selected in the sub-cell arrays SCA1 to SCAn corresponding to one row.

According to an embodiment, the row peripheral circuit 120 may be configured to control the unit cell circuits including the above-described assist circuits AC1 to ACn. The row peripheral circuit 120 may individually control the plurality of assist circuits AC1 to ACn or may control one or more assist circuits AC1 to ACn simultaneously or in common. The row peripheral circuit 120 may select one word line among the plurality of word lines WLS1 to WLSn and may activate one of the assist circuits AC1 to ACn corresponding to one of the sub-cell arrays SCA1 to SCAn connected to the selected word line. Activating the assist circuits AC1 to ACn may mean blocking the supply lines SL1 to SLn through the assist circuits AC1 to ACn when the write operation is initiated.

In addition, the row peripheral circuit 120 may pre-charge the supply lines SL1 to SLn to the supply voltage VDD through the assist circuits AC1 to ACn during the stand-by mode. For example, the assist circuits AC1 to ACn may pre-charge the supply lines SL1 to SLn to the supply voltage VDD based on at least one control signal from the row peripheral circuit 120 during the stand-by mode.

The column peripheral circuit 130 may be connected to the memory cell array 110 through the plurality of bit lines, and may activate a pair of bit lines among the plurality of bit lines BL1 to BLm and the plurality of inverted bit lines BLb1 to BLbm based on a column address C_ADDR. The column peripheral circuit 130 may activate a pair of bit lines during the read operation and may detect the current and/or the voltage received through the pair of bit lines, thereby reading the values stored in the memory cells corresponding to the activated word line. Additionally, the column peripheral circuit 130 may apply the current and/or the voltage to a pair of bit lines based on data to be written during the write operation.

The control circuit 140 may receive a command CMD and may control the row peripheral circuit 120 and the column peripheral circuit 130 based on the received command CMD. For example, the control circuit 140 may identify a read command or a write command by decoding the command CMD and may generate a control signal to perform the identified operation. The control circuit 140 may activate or deactivate the plurality of word lines WLS1 to WLSn and/or the plurality of bit lines BL1 to BLm and the plurality of inverted bit lines BLb1 to BLbm at timings determined based on the control signal.

According to an embodiment, the memory device 100 may further include a plurality of isolation circuits such as ISOLC1 and ISOLC2. The plurality of isolation circuits ISOLC1 and ISOLC2 may be configured between some sub-cell arrays of the sub-cell arrays SCA1 to SCAn. One isolation circuit may be connected to one of the sub-cell arrays SCA1 to SCAn, like the assist circuits AC1 to ACn. Each of the isolation circuits ISOLC1 and ISOLC2 may be configured to isolate the sub-cell arrays SCA1 to SCAn to prevent data interference or leakage between sub-cell arrays. Additionally, each of the isolation circuits ISOLC1 and ISOLC2 may be configured such that the connected sub-cell arrays SCA1 to SCAn share one of the supply lines SL1 to SLn.

According to the above-described embodiments, the memory device 100 of the present disclosure may include the plurality of unit cell circuits including the assist circuits AC1 to ACn and the sub-cell arrays SCA1 to SCAn, and may assist the write operation of each of the sub-cell arrays SCA1 to SCAn through the assist circuits AC1 to ACn. In particular, the memory device 100 of the present disclosure blocks the supply lines SL1 to SLn at the initiation of the write operation through the assist circuits AC1 to ACn to collapse the supply voltage VDD and lower the minimum operating voltage, and thus may improve write assistance performance compared to always activating the supply lines SL1 to SLn. Additionally, since the assist circuits AC1 to ACn are not disposed in the peripheral circuits, the area overhead due to the assist circuits AC1 to ACn may also be reduced.

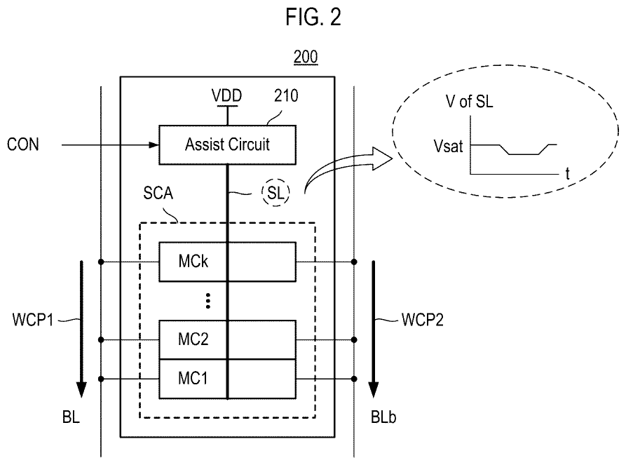

FIG. 2 illustrates a unit cell circuit, according to an embodiment.

Referring to FIG. 2, a unit cell circuit 200 according to an embodiment may be defined as including one sub-cell array selected from SCA1-SCAn and one corresponding assist circuit selected from AC1-ACn of FIG. 1.

The unit cell circuit 200 of FIG. 2 includes one sub-cell array SCA, which, in turn, includes a plurality of memory cells MC1 to MCk (e.g., ‘k’ memory cells MC1 to MCK) each connected to a supply line SL. The sub-cell array SCA is connected to an assist circuit 210 through the supply line SL. According to an embodiment, at least the plurality of memory cells MC1 to MCk included in the sub-cell array SCA may be commonly connected to the assist circuit 210 through one supply line SL.

The assist circuit 210 may assist the write operation of the sub-cell array SCA based on a control signal CON. For example, the control signal CON may be received through the row peripheral circuit of FIG. 1.

The assist circuit 210 may pre-charge the supply line SL to the supply voltage VDD during the stand-by mode based on the control signal CON.

When the write operation is initiated, the assist circuit 210 blocks the supply line SL. The voltage of the supply line SL (V of SL) collapses from the supply voltage VDD that is pre-charged to the level of a saturation voltage Vsat. In greater detail, write current paths WCP1 and WCP2 with respect to a bit line BL or a bit line bar BLb may be formed from the activated memory cells MC1 to MCk according to the initiation of the write operation. The write current paths WCP1 and WCP2 may vary depending on the selected memory cell among the plurality of memory cells MC1 to MCK, but in common, may be defined as a current path that flows to one of the bit lines via one selected memory of the memory cells MC1 to MCK from the supply line SL.

The write current paths WCP1 and WCP2 may be formed based on which bit line the data to be written to the activated memory cells MC1 to MCk is to be applied. For example, when the data to be written is applied to the bit line BL, the first write current path WCP1 may be formed, and when the data to be written is applied to the bit line bar BLb, the second write current path WCP2 may be formed, without limitation thereto.

Through the write current paths WCP1 and WCP2, the initial voltage of the supply line SL gradually collapses from the supply voltage VDD towards the saturation voltage Vsat. As the voltage of the supply line SL gradually collapses, the pull-up performance with respect to the write current paths WCP1 and WCP2 of the activated memory cells MC1 to MCk decreases, so write performance may be improved.

Afterwards, when the write operation for the activated memory cells MC1 to MCk is completed, the formed write current paths WCP1 and WCP2 are blocked again, and the assist circuit 210 may end the blocking of the supply line SL based on the control signal CON. Accordingly, the voltage of the supply line SL rises from the voltage at which the collapsing ends (e.g., no less than Vsat) to the supply voltage VDD.

According to the above-described embodiment, the unit cell circuit 200 of the present disclosure may have improved writing performance using the assist circuit 210 that may decrease the pull-up performance with respect to the memory cells MC1 to MCk through blocking the supply line SL. Additionally, since the assist circuit 210 is configured inside the unit cell circuit 200, area overhead may be reduced compared to when the assist circuit 210 is configured in one or more peripheral circuits.

In addition, when there is an internal resistance including a bit line resistance according to the connection of the bit lines and a resistance of the supply voltage VDD seen from the assist circuit 210, the amount of write current flowing through the write current paths WCP1 and WCP2 decreases. Nevertheless, the unit cell circuit 200 of the present disclosure may still have improved write performance since the pull-up performance is decreased by blocking the supply line SL.

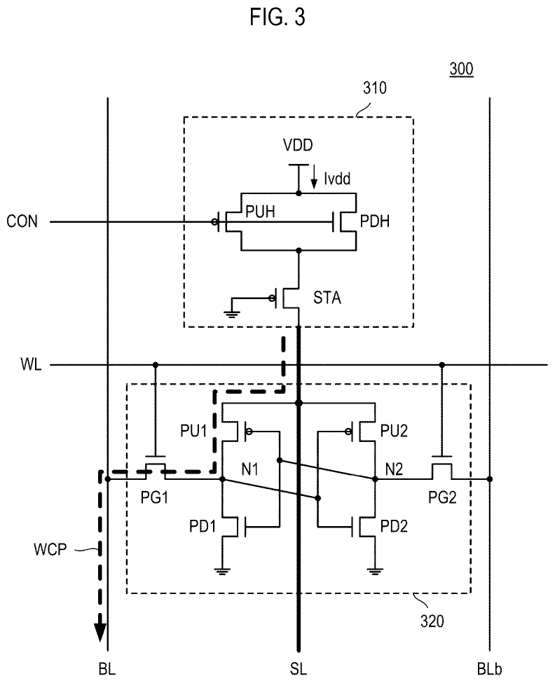

FIG. 3 illustrates a unit cell circuit according to an embodiment.

For convenience of description with respect to the unit cell circuit 300 of FIG. 3, only one memory cell 320 selected from the sub-cell array is illustrated without limitation thereto. Additionally, the illustrated memory cell 320 has a 6 T structure composed of six transistors, but embodiments of the present disclosure are not limited thereto, and the memory cell 320 may have an 8 T structure or another structure. The memory cell 320 may include a first pass gate transistor PG1 and a second pass gate transistor PG2 that are connected to the word line WL, a first pull-up transistor PU1 and a first pull-down transistor PD1 that form one inverter, and a second pull-up transistor PU2 and a second pull-down transistor PD2 that form another inverter.

The first pass gate transistor PG1 has a drain connected to a first node N1, a gate connected to the word line WL, and a source connected to the bit line BL. The second pass gate transistor PG2 has a drain connected to a second node N2, a gate connected to the word line WL, and a source connected to the bit line bar BLb. The first pass gate transistor PG1 and the second pass gate transistor PG2 are turned on when the word line WL is activated to select the memory cell 320. When the word line WL is inactivated, the first pass gate transistor PG1 and the second pass gate transistor PG2 are turned off so that the memory cell 320 holds the stored data.

The first pull-up transistor PU1 and the first pull-down transistor PD1 have drains commonly connected to the first node N1 and gates commonly connected to the second node N2. The second pull-up transistor PU2 and the second pull-down transistor PD2 have drains commonly connected to the second node N2 and gates commonly connected to the first node N1. Therefore, each inverter stores data opposite to each other. For convenience of description, it is assumed that data corresponding to a logic high value is stored in the first node N1, without limitation. It is further assumed that the write operation is to write data corresponding to a logic low value to the first node N1, without limitation.

An assist circuit 310 is connected to the sources of the first pull-up transistor PU1 and the second pull-up transistor PU2 through the supply line SL. The assist circuit 310 according to an embodiment may include a pull-up header transistor PUH, a pull-down header transistor PDH, and a stack transistor STA. However, this is only an embodiment of the present disclosure, and various embodiments associated with the configuration of the assist circuit 310 may be implemented, including but not limited to those described infra.

In an embodiment, the pull-up header transistor PUH has a gate to which the control signal CON is applied, a source to which the supply voltage VDD is applied, and a drain connected to a source of the stack transistor STA. The pull-down header transistor PDH may be configured in various ways such that a logic high value voltage is applied to its gate during the write operation. The pull-down header transistor PDH of FIG. 3 has the gate to which the control signal CON is applied and may be operated through the control signal CON. As the control signal CON is commonly applied to each gate of the pull-up header transistor PUH and the pull-down header transistor PDH and these transistors are of opposite polarity types, one of the pull-up header transistor PUH and the pull-down header transistor PDH may be turned on and the other of the pull-up header transistor PUH and the pull-down header transistor PDH may be turned off.

The stack transistor STA may be a PMOS transistor and have a gate to which a ground voltage is applied, and a drain connected to the supply line SL. Additionally, a source of the stack transistor STA is connected to the drain of the pull-up header transistor PUH and the source of the pull-down header transistor PDH. The stack transistor STA is always turned on by receiving the ground voltage to its gate. Accordingly, whether the supply voltage VDD is applied to the supply line SL is determined depending on the header transistors. In an embodiment, the stack transistor is optional.

To describe the write operation in detail, first, during the stand-by mode before the write operation, a logic level of the control signal CON may correspond to a logic low value. In greater detail, the pull-up header transistor PUH is turned on, the pull-down header transistor PDH is turned off, and the supply voltage VDD is pre-charged on the supply line SL. Additionally, even in the case of the read operation, the logic level of the control signal CON corresponds to a logic low value.

When the write operation is initiated, the word line WL is activated and the logic level of the control signal CON corresponds to a logic high value. According to an embodiment, each of the plurality of memory cells 320 is selected through the word line during the write operation, and the control signal CON may transition to a logic high value at a second timing that is a specific time period later than a first timing at which the word line is activated. In this case, in a situation where the word line WL is selected and the bit line BL is not selected, since the assist circuit 310 operates later than immediately after the word line WL is activated, which is the time when stability of maintaining the data stored in the memory cell 320 is most vulnerable, the stability need not deteriorate.

Alternatively, the second timing at which the control signal CON transitions may be simultaneous with the first timing, according to an embodiment. Even if the second timing and the first timing are substantially the same, the above-mentioned stability feature is optional, so it is also possible for the control signal CON to transition at the first timing.

Accordingly, the pull-up header transistor PUH is turned off. Additionally, since the gate voltage of the pull-down header transistor PDH corresponds to a logic high value and its source voltage is also the pre-charged supply voltage VDD, the pull-down header transistor PDH is turned off when the write operation is initiated. The pull-down header transistor PDH operates as a diode after the initiation of the write operation. Therefore, a current Ivdd flowing from the supply voltage VDD has a value of substantially ‘0’.

In the memory cell 320, as the first pull-up transistor PU1 is turned on and each pass gate transistor is turned on, a write current path WCP is formed through the bit line BL. Accordingly, the voltage of the supply line SL decreases. As the voltage of the supply line SL decreases, the pull-up performance of the first pull-up transistor PU1 to maintain a logic high value decreases, and thus the operation of writing logic low valued data into the memory cell 320 is assisted. Accordingly, the write performance with respect to the memory cell 320 may be improved. Additionally, since the source voltage of the pull-down header transistor PDH decreases as the voltage of the supply line SL collapses, the pull-down header transistor PDH may be turned on gradually.

When the write operation is successful, the first node N1 transitions to a logic low value and the second node N2 transitions to a logic high value. Accordingly, the first pull-up transistor PU1 is turned off and the write current path WCP is blocked. As the write current path WCP is blocked, the voltage on the supply line SL stops collapsing. Additionally, as the control signal CON transitions to a logic low value, and the pull-up header transistor PUH is turned on, the voltage of the supply line SL is pre-charged again on the supply line SL. During the pre-charge, the current lvdd flows from the supply voltage VDD.

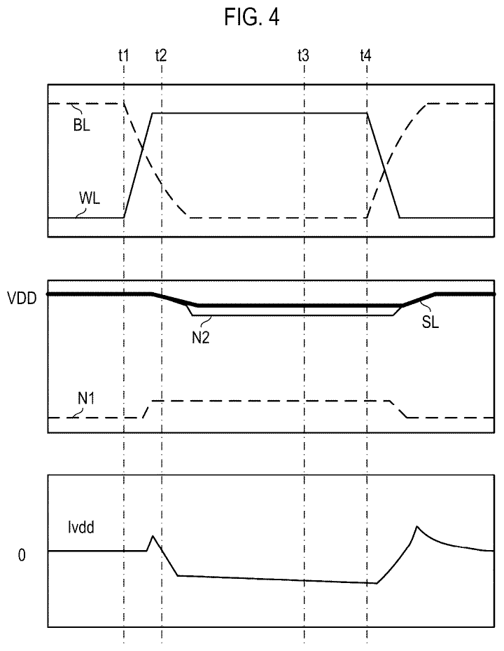

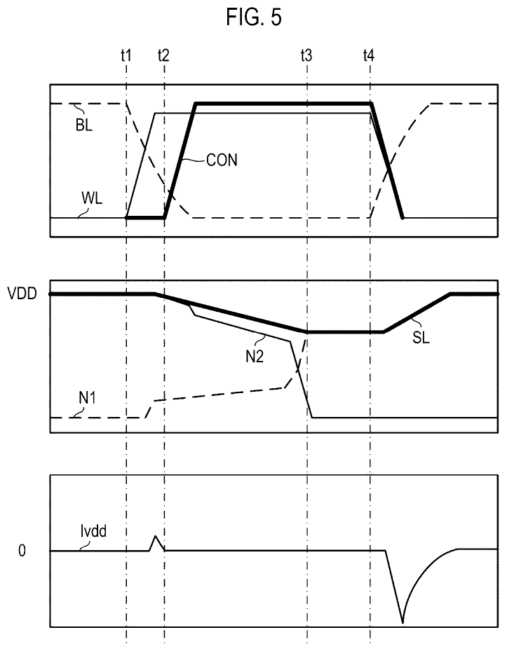

FIG. 4 illustrates operational waveforms of comparative examples, and FIG. 5 illustrates operational waveforms of FIG. 3. In the present disclosure, the comparative examples are some in which the assist circuit is configured to always supply the supply voltage VDD. Additionally, FIGS. 4 and 5 illustrate operational waveforms for cells with low write performance when high sigma ‘σ’ is desired.

Referring to FIGS. 4 and 5, before time t1 when the write operation initiates, the voltage of the supply line SL is pre-charged to the supply voltage VDD, and the voltage of the bit line BL is also pre-charged to a high bit line voltage. At time t1, the bit line BL transitions to a voltage corresponding to the data to be written, and the word line WL is activated. As the bit line BL and the word line WL transition from time t1, the voltage of the first node N1 gradually transitions from a logic low value to a logic high value, and the voltage of the second node N2 gradually transitions from a logic high value to a logic low value.

Time t2 may be defined as the time at which the logic state of the control signal CON transitions. The control signal CON transitions from a logic low value to a logic high value at time t2, which may be a specific time period after time t1. According to an embodiment, the control signal CON may transition to a logic high value at time t1.

However, the case of FIG. 4 is a comparative example assuming that the voltage of the supply line SL is always maintained regardless of the transition of the control signal CON, so a voltage drop rate of the supply line SL is relatively slow. In greater detail, the pull-up performance of a pull-up transistor of the memory cell decreases slowly, and the voltage of the supply line SL need not drop to a minimum operating voltage. Ultimately, in the comparative example of FIG. 4, the voltages of the first node N1 and the second node N2 might not transition such that the write operation may fail.

In contrast, in the case of FIG. 5 according to an embodiment, the pull-up header transistor PUH and pull-down header transistor PDH of the assist circuit are initially turned off at time t2, so the supply line SL is blocked and a write current path is formed in the memory cell. Therefore, the voltage of the supply line SL collapses relatively quickly. Accordingly, the minimum operating voltage may be satisfied, and the voltages of the first node N1 and the second node N2 successfully transition after time t3, so that the write operation is successful. Additionally, since the write current path is blocked depending on the success of the write operation, the voltage of the supply line SL is maintained at a specific level.

After time t4, the bit line BL is pre-charged again and the word line WL is deactivated. Additionally, the control signal CON also transitions from a logic high value to a logic low value. Accordingly, the supply voltage VDD is supplied from the assist circuit to the memory cell, the voltage of the supply line SL is pre-charged again to the supply voltage VDD, and the current Ivdd is formed.

According to the above-described embodiments, a unit cell circuit of the present disclosure may improve the performance of the write operation by improving the voltage collapse speed of the supply line SL and improving the minimum operating voltage when high sigma is desired.

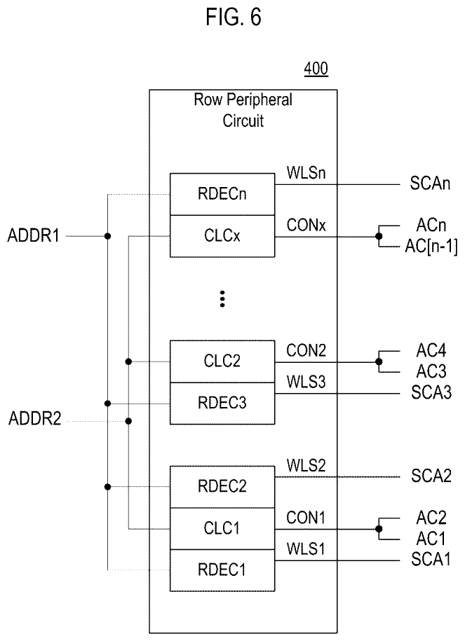

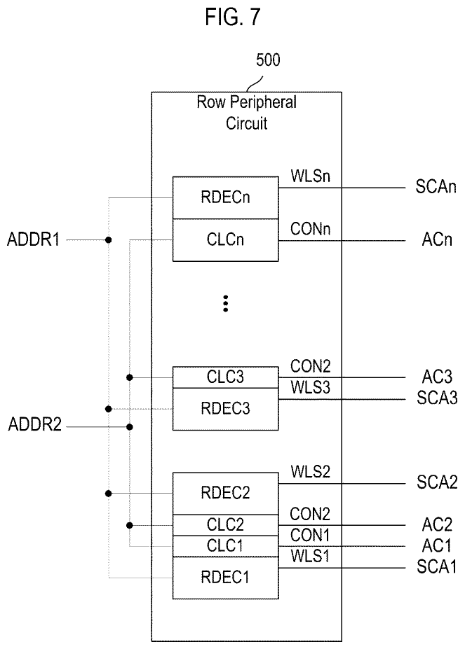

FIGS. 6 and 7 illustrate row peripheral circuits of FIG. 1, according to respective embodiments.

First, referring to FIG. 6, a row peripheral circuit 400 may include a plurality of row decoders RDEC1 to RDECn and a plurality of control logic circuits CLC1 to CLCx. For example, ‘n’ row decoders RDEC1 to RDECn may be configured, and ‘x’ control logic circuits CLC1 to CLCx may be configured (where ‘x’ is a natural number). For example, ‘x’ may be a natural number less than or equal to ‘n’.

The plurality of row decoders RDEC1 to RDECn are connected to a plurality of sub-cell arrays SCA1 to SCAn through a plurality of word lines WLS1 to WLSn. One row decoder is connected to one of the sub-cell arrays SCA1 to SCAN and may receive first address information ADDR1. The plurality of row decoders RDEC1 to RDECn may decode the first address information ADDR1 and may select and activate the plurality of word lines WLS1 to WLSn connected to the sub-cell arrays SCA1 to SCAn included in the memory cell array based on the decoded first address information ADDR1.

The plurality of control logic circuits CLC1 to CLCx control the assist circuits AC1 to ACn based on control signals CON1 to CONx. According to an embodiment, one control logic circuit may be connected to two assist circuits to control the two assist circuits based on one control signal, such as where ‘x’ is substantially equal to ‘n’/2. For example, the first control logic circuit CLC1 may be connected to the first assist circuit AC1 and the second assist circuit AC2 and may apply the first control signal CON1. Accordingly, the plurality of control logic circuits CLC1 to CLCx may simultaneously control two assist circuits among the plurality of assist circuits AC1 to ACn corresponding to the plurality of unit cell circuits. In addition, even if substantially the same control signal CON1 to CONx is applied to the two assist circuits AC1 to ACn, the sub-cell array SCA1 to SCAn corresponding to one word line activated through the row decoder RDEC1 to RDECn will operate according to the above-described embodiments.

The plurality of control logic circuits CLC1 to CLCx may generate the control signals CON1 to CONx based on second address information ADDR2. In this case, the second address information ADDR2 may be defined to select the assist circuits AC1 to ACn connected to the sub-cell arrays SCA1 to SCAn corresponding to the word lines WLS1 to WLSn to be selected.

Alternatively, ‘n’ number of control logic circuits CLC1 to CLCn may be configured as illustrated in FIG. 7. In greater detail, the number of control logic circuits CLC1 to CLCn may be substantially the same as the number of assist circuits AC1 to ACn. In this case, one control logic circuit is connected to one assist circuit and may control one assist circuit based on the control signal CON. For example, the first control logic circuit CLC1 may control the first assist circuit AC1 based on the first control signal CON1. Furthermore, the number and configuration of the control logic circuits are not limited to the above-described embodiments, and the control logic circuits may be implemented in various ways such that one or more control signals is applied to the assist circuits AC1 to ACn connected to the sub-cell array selected by the word lines WLS1 to WLSn.

According to the above-described embodiments, the row peripheral circuit of the present disclosure may allow the assist circuit configured in the memory cell array to assist the write operation through the control logic circuit.

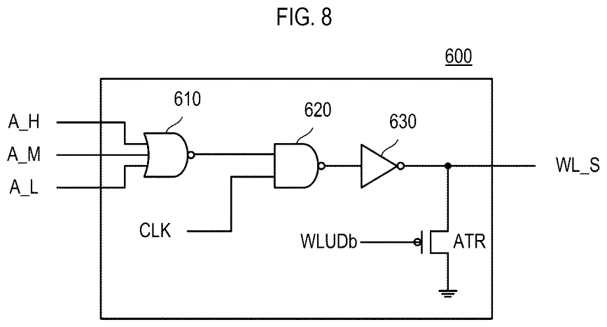

FIG. 8 illustrates a row decoder applicable to the embodiments of FIGS. 6 and 7 according to a respective embodiment.

Referring to FIG. 8, a row decoder 600 according to an embodiment may include a first NOR gate 610, a first NAND gate 620, and a NOT gate 630. The first NOR gate 610 may receive address bit information corresponding to first address information and may perform a NOR operation. In this case, the bit information is illustrated as A_H corresponding to a most significant bit (MSB), A_M corresponding to a middle bit, and A_L corresponding to a least significant bit (LSB), but alternatively or in addition, the first address information may be configured in various ways to select a word line without limitation thereto.

The first NAND gate 620 performs a NAND operation on the result of the NOR operation and a clock signal CLK. Accordingly, the address bit information may be sampled according to the clock signal CLK. The NOT gate 630 is connected to the output of the first NAND gate 620 and may output a word line signal WL_S for selecting the word line.

According to an embodiment, the row decoder 600 may further include an assist transistor ATR. The assist transistor ATR may have a drain connected to an output terminal of the NOT gate 630, a source connected to ground, and a gate to which a bar signal WLUDb of a word line under drive signal is applied. The assist transistor ATR may be turned on or off depending on the bar signal WLUDb to assist performance of the read operation.

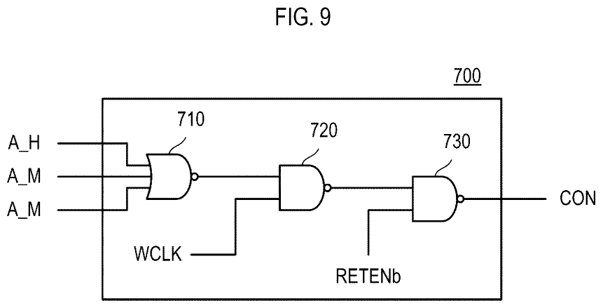

FIG. 9 illustrates a control logic circuit applicable to the embodiment of FIG. 6 according to an embodiment.

Referring to FIG. 9, a control logic circuit 700 according to an embodiment may include a second NOR gate 710, a second NAND gate 720, and a third NAND gate 730.

The second NOR gate 710 may receive address bit information corresponding to second address information and may perform a NOR operation. By way of example, the address bit information may include the above-described A_H and A_M. In this case, the control logic circuit 700 is capable of controlling one or more assist circuits. Alternatively, address bit information may be configured in various ways to select the assist circuit without limitation.

The second NAND gate 720 may sample address bit information by performing a NAND operation on the result of the NOR operation and a write clock signal WCLK. The third NAND gate 730 may perform a NAND operation on the NAND operation result of the second NAND gate 720 and a retention signal RETENb to output the control signal CON. In other than the retention mode, the retention signal RETENb has a value of a logic high value. In the retention mode, the retention signal RETENb has a logic value corresponding to a logic low value, and thus the control signal CON always has a logic high value during the retention mode. As described above, the retention mode is a mode that reduces leakage power while maintaining data stored in memory cells by turning down power of peripheral circuits (e.g., the column peripheral circuits in FIG. 1) and supplying power to the memory cell array.

In an alternate embodiment, a similar control logic circuit may be applicable to the embodiment of FIG. 7 with minor modification, such using a triple-input NOR gate further receiving A_L in place of the double-input NOR gate 710, or potentially by omitting the second NOR gate 710 and obtaining the first input to the second NAND gate 720 from the first NOR gate 610 of FIG. 7. Substantially duplicate description may be omitted.

FIGS. 8 and 9 described above are merely example circuits of the row decoder and the control logic circuit. Alternatively, the row decoder and the control logic circuit may be configured to perform operations and functions according to the embodiments of FIGS. 1 to 7, respectively.

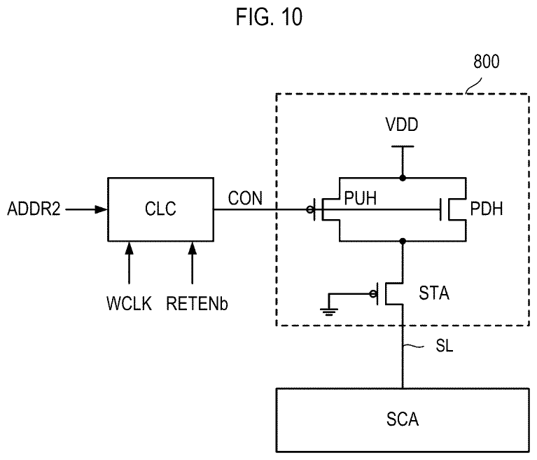

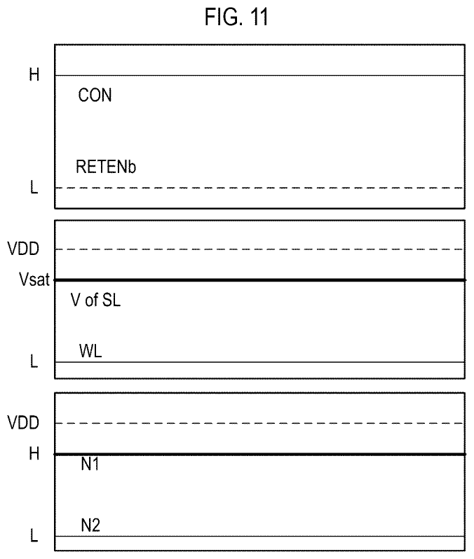

FIG. 10 illustrates a control logic circuit and a unit cell circuit for performing a retention mode operation according to an embodiment, and FIG. 11 illustrates operational waveforms of FIG. 10.

Referring to FIGS. 10 and 11, a control logic circuit CLC according to an embodiment may generate the control signal CON based on the second address information ADDR2, the write clock signal WCLK, and the retention signal RETENb. The control signal CON may be generated such that an assist circuit 800 blocks the supply line SL to the sub-cell array SCA when the retention mode starts. In greater detail, as described above, the retention signal RETENb may be defined such that the logic level of the control signal CON corresponds to a logic high value during the retention mode. For example, the retention signal RETENb may have a logic low value. Accordingly, the control signal CON output from the control logic circuit CLC has a logic high value in the retention mode. According to an embodiment, in the retention mode, all control logic circuits included in the memory device may output a control signal having a logic high value.

Additionally, in the retention mode, the respective word line is deactivated, so the voltage of the word line corresponds to a logic low value, and the data (e.g., voltages of the first and second nodes in FIG. 3) stored in the memory cell will also maintain the stored logic state.

When the control signal CON corresponding to a logic high value is applied to the gates of the pull-up header transistor PUH and the pull-down header transistor PDH included in the assist circuit 800, the pull-up header transistor PUH is turned off and the pull-down header transistor PDH may operate like a diode, similar to the case of initiating the write operation. The stack transistor STA is always turned on. The pull-down header transistor PDH may gradually turn on to allow a pull-up current to flow to the supply line SL.

The pull-up current generated by the pull-down header transistor PDH may prevent a voltage drop on the supply line SL due to leakage current with respect to the memory cell array, including the sub-cell array. For example, the voltage of the supply line SL may converge to a level Vsat at which the leakage current and the pull-up current generated by the pull-down header transistor PDH have substantially the same level.

By preventing the voltage of the supply line SL from collapsing to the ground level due to the pull-up current, data retention performance in the retention mode may be improved. In particular, according to the present disclosure, it is possible to lower leakage current through the assist circuit 800 included within the memory cell array rather than the peripheral circuit. In greater detail, the assist circuit 800 of the present disclosure not only may assist the write performance, but also may improve the retention performance in the retention mode by lowering leakage current.

Below, various embodiments of the assist circuit according to the above-described embodiments are described.

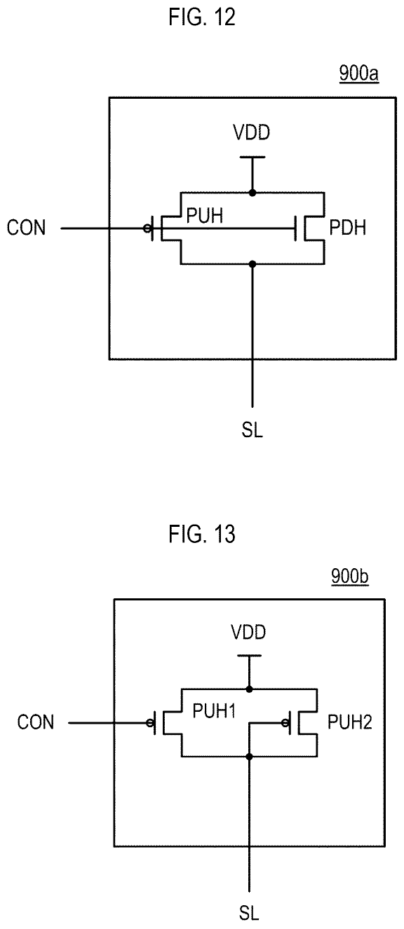

FIGS. 12 to 17 illustrate assist circuits according to respective embodiments.

Referring to FIG. 12, an assist circuit 900a according to an embodiment may include the pull-up header transistor PUH and the pull-down header transistor PDH, but need not include any stack transistor. The pull-up header transistor PUH may have a gate to which the control signal CON is applied, a source to which the supply voltage VDD is applied, and a drain that is directly connected to the supply line SL. The pull-down header transistor PDH may have a gate to which the control signal CON is applied, a drain to which the supply voltage VDD is applied, and a source that is directly connected to the supply line SL. In greater detail, the assist circuit 900a of FIG. 12 is implemented by omitting the stack transistor STA from the assist circuit 310 of FIG. 3. One of the pull-up header transistors PUH and the pull-down header transistor PDH may be turned on and the other may be turned off depending on the control signal CON that is commonly used.

According to an embodiment, when the write operation is initiated, the pull-up header transistor PUH is turned off and the pull-down header transistor PDH is turned on, thereby blocking the supply line SL and assisting the write performance.

Referring to FIG. 13, an assist circuit 900b according to an embodiment may include a first pull-up header transistor PUH1 and a second pull-up header transistor PUH2. The control signal CON is applied to the gate of the first pull-up header transistor PUH1, but the gate of the second pull-up header transistor PUH2 may be connected to the supply line SL. In greater detail, the supply voltage VDD is applied to the source of the second pull-up header transistor PUH2, and its gate and its drain are both connected to the supply line SL. Therefore, the second pull-up header transistor PUH2 is turned off when the control signal CON is a logic low value, and when the control signal CON becomes a logic high value at the initiation of the write operation, the second pull-up header transistor PUH2 may block the supply line SL and then may be turned on more gradually.

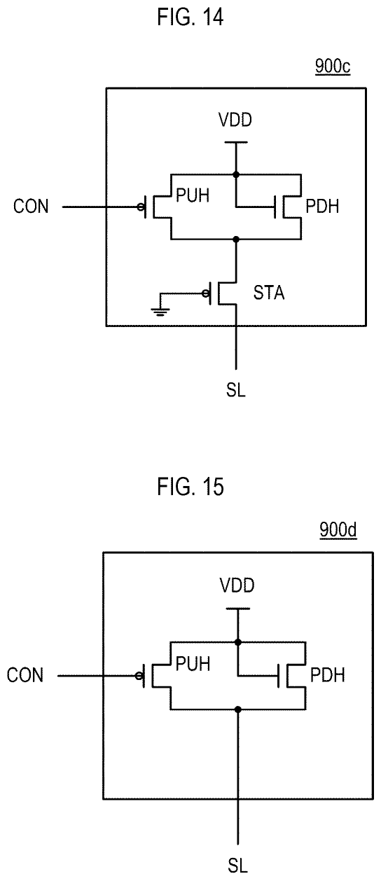

Referring to FIG. 14, an assist circuit 900c according to an embodiment may include the pull-up header transistor PUH, the pull-down header transistor PDH, and the stack transistor STA. Except for the pull-down header transistor PDH, the connection relationship of the remaining transistors is substantially the same as in FIG. 3. The pull-down header transistor PDH may have a structure in which a gate and a drain are connected to each other or both connected to the supply voltage line. In greater detail, an operating voltage corresponding to a logic high value, such as VDD, is always applied to the gate of the pull-down header transistor PDH. Ultimately, during the write operation, as in the above description FIG. 3, the pull-down header transistor PDH blocks the supply line SL and then gradually turns on.

Referring to FIG. 15, an assist circuit 900d according to an embodiment may have a structure in which the stack transistor STA is omitted from the assist circuit 900c of FIG. 14. Even if the stack transistor STA is omitted or removed, the operation of the assist circuit 900d that assists the write performance by blocking the supply line SL during the write operation, or the operation of the pull-down header transistor PDH that prevents extreme collapsing of the supply line SL in the retention mode is substantially the same as in FIG. 14.

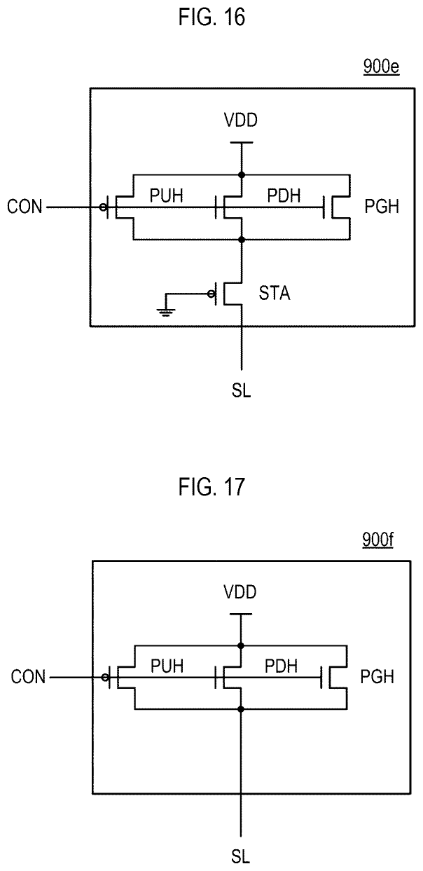

Referring to FIGS. 16 and 17, each of assist circuits 900e and 900f according to a respective embodiment, may include the pull-up header transistor PUH, the pull-down header transistor PDH, and a pass gate header transistor PGH. Like the pull-down header transistor PDH, the pass gate header transistor PGH may have a gate to which the control signal CON is applied and a drain to which the supply voltage VDD is applied. A source of the pass gate header transistor PGH may be connected to the source of the stack transistor STA as in the embodiment 900e of FIG. 16; or may be directly connected to the supply line SL as in the embodiment 900f of FIG. 17. In greater detail, during the write operation, the pull-down header transistor PDH and the pass gate header transistor PGH together block the supply line SL and may be gradually turned on.

In the assist circuits of FIGS. 12 to 15 described above, the pull-down header transistor PDH may be replaced with the pass gate header transistor PGH. In addition, the pull-up header transistor PUH, the pull-down header transistor PDH, and the pass-gate header transistor PGH may be composed of substantially the same transistors as the pull-up transistor, the pull-down transistor, and the pass-gate header transistor PGH included in the memory cell, respectively.

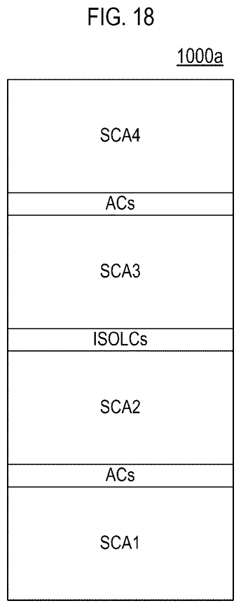

FIGS. 18 to 20 illustrate memory devices according to respective embodiments.

Referring to FIGS. 18 to 20, memory devices 1000a to 1000c may be implemented in various ways depending on the configuration of each sub-cell array. For example, the number and arrangement of assist circuits and the number and arrangement of isolation circuits may be configured depending on the number of memory cells included in each sub-cell array.

Assuming a memory device with a capacity of 256 bits, for example, when each sub-cell array is composed of 64 bits and organized as illustrated in FIG. 18, the memory device 1000a may include four sub-cell arrays. The assist circuits ACs are disposed between the first sub-cell array SCA1 and the second sub-cell array SCA2, and disposed between the third sub-cell array SCA3 and the fourth sub-cell array SCA4, and each assist circuit is connected to each adjacent sub-cell array. In addition, the isolation circuits ISOLCs are connected between the second sub-cell array SCA2 and the third sub-cell array SCA3 to support cell array isolation and split connection of the supply line SL.

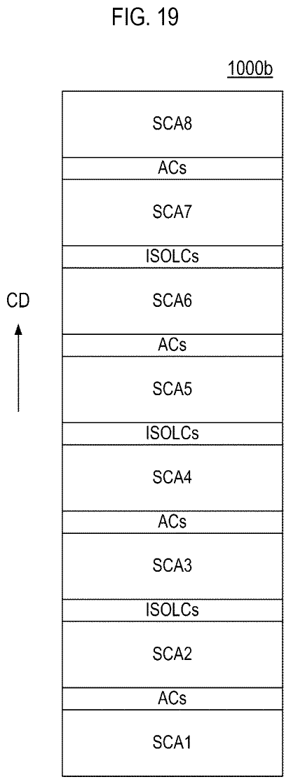

Alternatively, in a memory device with a capacity of 256 bits, for example, when each sub-cell array is composed of 32 bits and organized as illustrated in FIG. 19, the memory device 1000b may include 8 sub-cell arrays. The assist circuits ACs are connected between the first sub-cell array SCA1 and the second sub-cell array SCA2 among the sub-cell arrays defined along a column direction CD, and also, the assist circuits ACs are connected between the last sub-cell array SCA8 and the next to last sub-cell array SCA7. One assist circuit is connected to each sub-cell array. With respect to the remaining sub-cell arrays, the sub-cell arrays with the assist circuits ACs connected therebetween in the column direction and the sub-cell arrays with isolation circuits ISOLCs connected therebetween in the column direction may be configured by sequentially repeating.

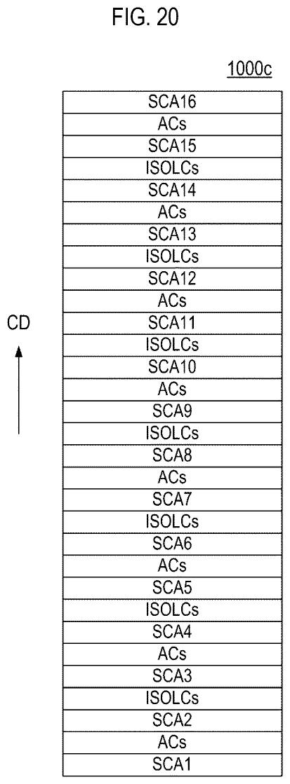

Alternatively, in a memory device with a capacity of 256 bits, for example, when each sub-cell array is composed of 16 bits and organized as illustrated in FIG. 20, the memory device 1000c may include 16 sub-cell arrays. The assist circuits ACs are connected between the first sub-cell array SCA1 and the second sub-cell array SCA2 among the sub-cell arrays defined along the column direction CD, and also, the assist circuits ACs are connected between the last sub-cell array SCA16 and the next to last sub-cell array SCA15. Other sub-cell arrays may be configured by sequentially repeating the assist circuits ACs, the sub-cell array, and the isolation circuits ISOLCs in the column direction, as illustrated in FIG. 19.

According to the above-described embodiments, in the memory device of the present disclosure, the assist circuit for assisting the write performance may be configured in the cell array area of the memory device rather than the peripheral circuit, so area overhead may be reduced. In alternate embodiments, the memory device may have an arbitrary number of bits, which may be divided among the numbers of sub-cell arrays set forth in any of the above-described embodiments and/or alternate arrangements thereof, without limitation thereto.

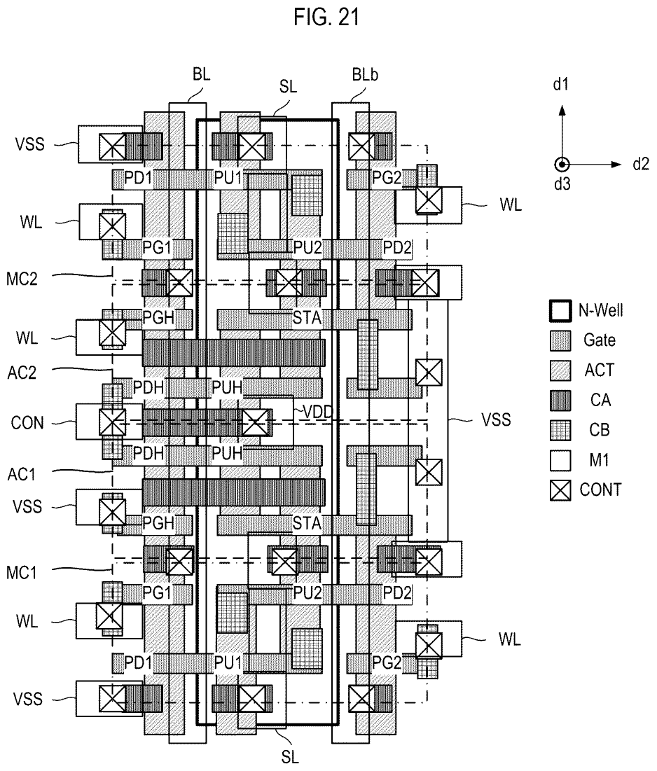

FIG. 21 illustrates a layout of a memory device, according to an embodiment. By way of example, FIG. 21 illustrates a layout of the assist circuit of FIG. 16 and the memory cell of FIG. 3, without limitation thereto.

Referring to FIG. 21, a memory device according to an embodiment may include N-type regions N-Well, gate electrodes Gate, active regions ACT, vertical routing or CA layers CA, horizontal routing or CB layers CB, wiring layers M1, and contacts CONT. At least some of each region, each layer, and each contact may form the memory cell and/or the assist circuit according to the above-described embodiments. The assist circuit is configured with a layout compatible with the memory cells as illustrated.

The layout of the first memory cell MC1 and the second memory cell MC2 may be substantially the same, and the layout of the first assist circuit AC1 and the second assist circuit AC2 may be substantially the same. Additionally, the layout of the first memory cell MC1 and the first assist circuit AC1 may be implemented adjacent to each other, and the layout of the second memory cell MC2 and the second assist circuit AC2 may also be implemented adjacent to each other. That is, the layouts of the memory cells and assist circuits are compatible with each other.

To form each memory cell, gate electrodes PU1, PU2, PD1, PD2, PG1, and PG2 each corresponding to the transistors in FIG. 4 are disposed, and to form each assist circuit, gate electrodes PUH, PDH, PGH, and STA each corresponding to the transistors in FIG. 16 are disposed. In this case, PU1, PU2, PD1, PD2, PG1, and PG2 may sequentially correspond to the gate electrodes of the first pull-up transistor, the second pull-up transistor, the first pull-down transistor, the second pull-down transistor, the first pass gate transistor, and the second pass gate transistor, respectively. In addition, PUH, PDH, PGH, and STA may sequentially correspond to the gate electrodes of the pull-up header transistor, the pull-down header transistor, the pass gate header transistor, and the stack transistor, respectively.

The wiring layers are connected to source/drain regions and/or gate electrodes through contacts. The wiring layers may correspond to one of the word line WL, the ground corresponding to the ground voltage VSS, the wiring line to which the control signal CON is applied, the bit line and bit line bar BL and BLb, and the supply line SL, as illustrated through FIGS. 3 and 16.

According to an embodiment, the n-type region, the active regions disposed on the n-type region, the gate electrodes disposed on the active regions, the CA layers, the CB layers disposed on gate electrodes, wiring layers corresponding to the bit line and the bit line bar connected to other layers through contacts, wiring layers to which the ground voltage is applied, wiring layers corresponding to the word line, and wiring layers to which the supply voltage are sequentially disposed along a d3 direction.

Referring to the first memory cell MC1 and the second memory cell MC2, a plurality of active regions may be disposed to extend along a d1 direction, and the gate electrodes PU1, PU2, PD1, PD2, PG1, and PG2 may be disposed on each active region to extend along a d2 direction. A wiring layer corresponding to the ground voltage VSS is connected to the active region where PD1 and PG1 are placed through the CA layer, and a wiring layer corresponding to the word line WL is connected to PG1 through the CB layer. PU1 is connected to PD1.

PU2 and PD2 are connected to each other, and the wiring layer corresponding to the word line WL is connected to PG2 through the CB layer. The wiring layer corresponding to the ground voltage VSS is connected to PD2 through the CA layer. The wiring layer corresponding to the supply line SL is connected to PU1 and PU2.

Looking at the first and second assist circuits AC1 and AC2, PGH, STA, PDH, and PUH may be disposed to extend on the plurality of active regions along the d2 direction. The plurality of active regions may be connected to each other through the CA layers extending along the d2 direction.

The wiring layer corresponding to the ground voltage VSS is connected to PGH and STA, and PDH and PUH are connected to each other. The wiring layer to which the control signal CON is applied through the CB layer is connected to the PDH, and the wiring layer to which the supply voltage VDD is applied is connected to the PUH.

According to the above-described embodiments, the gate electrodes and the CA layers of the first and second assist circuits AC1 and AC2 are disposed to extend along the d2 direction, so that the source, the gate, and the drain may be shared with each other. The first assist circuit AC1 and the second assist circuit AC2 may be formed in pairs between the memory cells.

In particular, the transistors of the assist circuit may be configured to have substantially the same width and/or height as the transistors of the memory cell, or may be configured to have substantially the same gate pitch and/or pattern as the transistors of the memory cell. The pull-up header transistor PUH, the pull-down header transistor PDH, and the stack transistor STA of the assist circuit may be configured using substantially the same footprint as the pull-up transistors PU1 and PU2 and one pull-down transistor (PD1 or PD2) of the memory cell. Additionally, each of the junctions of pull-up header transistor PUH and the pull-down header transistor PDH may be connected through further increasing the CA layers.

According to the above-described embodiments, in the memory device of the present disclosure, the assist circuit has a layout compatible with the memory cell, so that the assist circuit may be implemented without a separate dummy cell or a space. Therefore, area overhead may be reduced.

According to an embodiment of the present disclosure, the unit cell circuit for assisting a write operation and the memory device including the unit cell circuit may be provided.

The above descriptions are specific embodiments for carrying out the present disclosure. Embodiments in which a design is changed simply or which are easily changed may be included in the present disclosure as well as an embodiment described above. In addition, technologies that are easily changed and implemented by using the above embodiments may be included in the present disclosure. While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A unit cell circuit of a memory cell array, the unit cell circuit comprising:
a sub-cell array including a plurality of memory cells each connected to a supply line; and
an assist circuit connected to the sub-cell array through the supply line and configured to pre-charge the supply line with a supply voltage during a stand-by mode based on a control signal and to block the supply line upon initiation of a write operation.

2. The unit cell circuit of claim 1,
wherein the memory cell array comprises a plurality of unit cell circuits,
wherein a voltage of the supply line collapses from the supply voltage based on the assist circuit blocking the supply line during the write operation.

3. The unit cell circuit of claim 2, wherein the voltage of the supply line stops collapsing based on the write operation on one of the plurality of memory cells succeeding.

4. The unit cell circuit of claim 1, wherein, the assist circuit is configured to:
form a pull-up current on the supply line based on the collapsing of the voltage of the supply line after the initiation of the write operation.

5. The unit cell circuit of claim 1, wherein the assist circuit includes:
a first transistor having a gate configured to receive the control signal, a source configured to receive the supply voltage, and a drain connected to the supply line; and
a second transistor having a gate configured to receive a logic high valued voltage during the write operation, a drain configured to receive the supply voltage, and a source connected to the supply line.

6. The unit cell circuit of claim 5, wherein the control signal is commonly applied to the gate of the first transistor and the gate of the second transistor.

7. The unit cell circuit of claim 5, wherein the second transistor has its gate and its drain connected to each other.

8. The unit cell circuit of claim 1, wherein the assist circuit includes:
a stack transistor having a gate configured to receive a ground voltage and a drain connected to the supply line;
a first transistor having a gate configured to receive the control signal, a source configured to receive the supply voltage, and a drain connected to a source of the stack transistor; and
a second transistor having a gate configured to receive a logic high valued voltage during the write operation, a drain configured to receive the supply voltage, and a source connected to the drain of the stack transistor.

9. The unit cell circuit of claim 1, wherein the assist circuit includes:
a first transistor having a gate configured to receive the control signal, a source configured to receive the supply voltage, and a drain connected to the supply line; and
a third transistor having a gate and a drain that are connected to the supply line and having a source configured to receive the supply voltage.

10. The unit cell circuit of claim 1, wherein the control signal corresponds to a logic low value during the stand-by mode and corresponds to a logic high value during the write operation.

11. The unit cell circuit of claim 10,
wherein each of the plurality of memory cells is selected through a word line during the write operation, and
wherein the control signal transitions to a logic high value at a first timing when the word line is activated or at a second timing after a specific time period elapses.

12. The unit cell circuit of claim 1, wherein the supply line is configured for the sub-cell array through the assist circuit.

13. A memory device comprising:
a memory cell array including a plurality of unit cell circuits; and
a row peripheral circuit configured to control the plurality of unit cell circuits,
wherein each of the plurality of unit cell circuits includes:
a respective sub-cell array including a respective plurality of memory cells; and
a respective assist circuit connected to the respective sub-cell array through a respective supply line, and configured to pre-charge the respective supply line with a supply voltage during a stand-by mode based on a control of the row peripheral circuit and to block the respective supply line upon initiation of a write operation.

14. The memory device of claim 13, wherein the row peripheral circuit includes:
a plurality of row decoders configured to select a plurality of word lines connected to the memory cell array based on first address information; and
a plurality of control logic circuits configured to control the assist circuit based on a control signal.

15. The memory device of claim 14, wherein each of the plurality of control logic circuits is configured to simultaneously control two assist circuits among a plurality of assist circuits corresponding to the plurality of unit cell circuits.

16. The memory device of claim 14, wherein each of the plurality of control logic circuits is configured to generate its control signal based on second address information, a write clock signal, and a retention signal.

17. The memory device of claim 16, wherein the retention signal is defined such that the control signal corresponds to a logic high value in a retention mode.

18. A memory row circuit comprising:
a control logic circuit configured to provide a control signal; and
a unit cell circuit comprising:
an assist circuit configured to receive the control signal, pre-charge a supply line with a supply voltage during a stand-by mode based on the control signal and to block the supply line upon initiation of a write operation; and a sub-cell array including a plurality of memory cells each connected to the supply line.

19. The memory row circuit of claim 18, wherein the control logic circuit generates the control signal based on address information, a write clock signal, and a retention signal for a retention mode.

20. The memory row circuit of claim 19, wherein the control signal is generated to cause the assist circuit to block the supply line when the retention mode initiates.
